(19) United States
(12) Patent Application Publication
(10) Pub. No.: US 2026/0198377 A1
(43) Pub. Date: Jul. 9, 2026

(54) SEMICONDUCTOR PACKAGE AND MANUFACTURING METHOD THEREOF

(71) Applicant: Orient Semiconductor Electronics, Limited, Kaohsiung City (TW)

(72) Inventors: YUEH-MING TUNG, Kaohsiung City (TW); CHIA-MING YANG, Kaohsiung City (TW); PO-YEN YEN, Kaohsiung City (TW); PIN-CHUN WANG, Kaohsiung City (TW); GUAN-LIN PAN, Kaohsiung City (TW)

(21) Appl. No.: 19/070,574

(22) Filed: Mar. 5, 2025

(30) Foreign Application Priority Data
Jan. 3, 2025 (TW) 114100360

(51) Int. Cl. H01L 25/16; H01L 21/48; H01L 23/00; H01L 23/14; H01L 23/498; H01L 23/538; H01L 25/00; H01L 25/065; H10B 80/00; H10D 80/30

(52) U.S. Cl. CPC H10W 90/00; H10B 80/00; H10D 80/30; H10W 70/093; H10W 70/095; H10W 70/611; H10W 70/65; H10W 70/698; H10W 90/401; H10W 90/701; H10W 90/721; H10W 90/724

(57) ABSTRACT

The present disclosure provides a semiconductor package. The semiconductor package includes a base substrate, an intermediate substrate, a plurality of first conductive bumps, a graphics processing unit, and a plurality of second conductive bumps. The intermediate substrate is disposed on the base substrate. The first conductive bumps are disposed between and electrically connected to the base substrate and the intermediate substrate. The graphics processing unit is disposed on the intermediate substrate. The second conductive bumps are disposed between and electrically connected to the intermediate substrate and the graphics processing unit. The second conductive bumps are electrically connected to the first conductive bumps through the intermediate substrate. The present disclosure further provides a method of manufacturing the above semiconductor package.

### CROSS-REFERENCE TO RELATED APPLICATIONS

The present application is based on and claims priority to Taiwanese Application Number 114100360, filed Jan. 3, 2025, the disclosure of which is hereby incorporated by reference herein in its entirety.

### FIELD OF THE DISCLOSURE

This disclosure relates to a semiconductor package and a manufacturing method thereof, and more particularly relates to a high-computing semiconductor package, and a manufacturing method thereof.

### BACKGROUND OF THE DISCLOSURE

At present, the manufacturing cost of high-computing semiconductor packages is too high and their yield is not easy to control.

### SUMMARY

In view of the above, the present disclosure provides a semiconductor package and a manufacturing method thereof to solve the above problems.

In one embodiment, the semiconductor package of the present disclosure includes a base substrate, an intermediate substrate, a plurality of first conductive bumps, a graphics processing unit, and a plurality of second conductive bumps. The intermediate substrate is disposed on the base substrate. The first conductive bumps are disposed between and electrically connected to the base substrate and the intermediate substrate. The graphics processing unit is disposed on the intermediate substrate. The second conductive bumps are disposed between and electrically connected to the intermediate substrate and the graphics processing unit. The second conductive bumps are electrically connected to the first conductive bumps through the intermediate substrate.

In another embodiment, the method of manufacturing a semiconductor package comprises: forming a plurality of first conductive bumps on an intermediate substrate; disposing the intermediate substrate on a base substrate such that the first conductive bumps are disposed between the base substrate and the intermediate substrate and the first conductive bumps are electrically connected to the base substrate and the intermediate substrate; forming a plurality of second conductive bumps on a graphics processing unit; and disposing the graphics processing unit on the intermediate substrate such that the second conductive bumps are disposed between the intermediate substrate and the graphics processing unit and the second conductive bumps are electrically connected to the intermediate substrate and the graphics processing unit, wherein the second conductive bumps are electrically connected to the first conductive bumps through the intermediate substrate.

The semiconductor packages of the present disclosure have lower manufacturing costs and higher production yields.

The foregoing, as well as additional objects, features and advantages of the disclosure will be more readily apparent from the following detailed description, which proceeds with reference to the accompanying drawings.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of the semiconductor package of the present disclosure.

FIGS. 2 to 9 illustrate the method of manufacturing the semiconductor package of FIG. 1.

### DETAILED DESCRIPTION OF THE DISCLOSURE

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatial relative terms, such as “beneath.” “below,” “lower,” “above,” “upper” and the like, may be used herein for ease of description to describe one element or feature's relationship to another element(s) or feature(s) as illustrated in the figures. The spatial relative terms are intended to encompass different orientations of the device in use or operation in addition to the orientation depicted in the figures. The apparatus may be otherwise oriented (rotated 90 degrees or at other orientations) and the spatial relative descriptors used herein may likewise be interpreted accordingly.

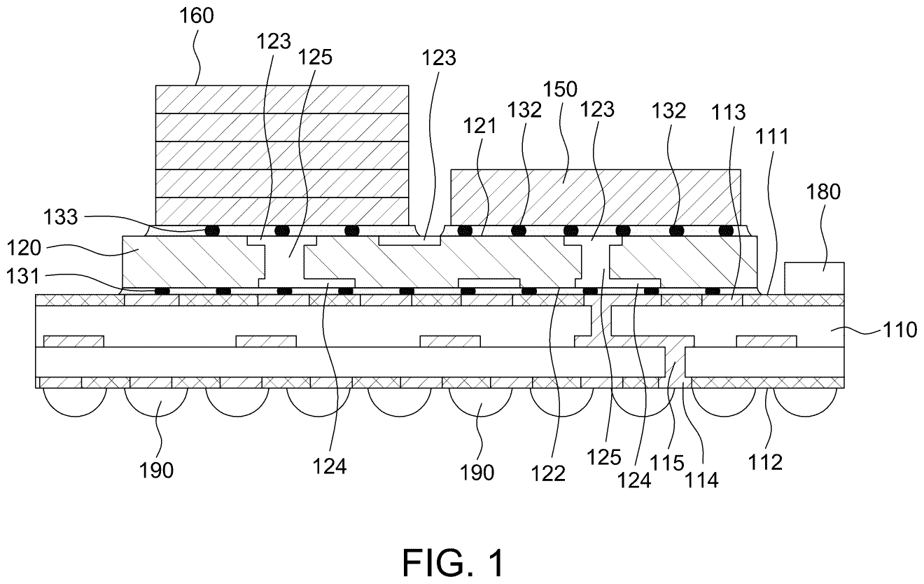

Referring to FIG. 1, the semiconductor package of the present disclosure includes a base substrate 110 having opposing first surface 111 and second surface 112, and the first surface 111 and the second surface 112 are located on different planes. For example, the first surface 111 is a top surface and the second surface 112 is a bottom surface, but is not limited thereto. The first surface 111 and the second surface 112 of the base substrate 110 are formed with a conductive trace 113 and a conductive trace 114 thereon, respectively. The conductive traces 113 and 114 are electrically connected to each other by a plurality of conductive vias 115 penetrating the base substrate 110 from the first surface 111 to the second surface 112. A plurality of passive components 180 may be mounted on the first surface 111 of the base substrate 110 as desired.

In one embodiment, the base substrate 110 may be a single-layer or multi-layer circuit board, a redistribution layer (RDL) substrate or a glass substrate.

An intermediate substrate 120 is positioned on the first surface 111 of the base substrate 110. The intermediate substrate 120 has opposing first surface 121 and second surface 122, and the first surface 121 and the second surface 122 are located on different planes. For example, the first surface 121 is a top surface and the second surface 122 is a bottom surface, but is not limited thereto.

In one embodiment, the intermediate substrate 120 may be a silicon substrate and be constructed of silicon.

The first surface 121 and the second surface 122 of the intermediate substrate 120 are formed with a conductive trace 123 and a conductive trace 124 thereon, respectively. The conductive traces 123 and 124 are electrically connected to each other by a plurality of conductive vias 125 penetrating the intermediate substrate 120 from the first surface 121 to the second surface 122.

In the present disclosure, the conductive trace 123 includes circuits for connecting a computing processor with a memory, and logic circuits for a high-computing memory.

A plurality of first conductive bumps 131 is disposed on the second surface 122 of the intermediate substrate 120 and sandwiched between the intermediate substrate 120 and the base substrate 110. The intermediate substrate 120 is electrically connected to the base substrate 110 through the first conductive bumps 131. A gap between the intermediate substrate 120 and the base substrate 110 is infiltrated with underfill to cover the first conductive bumps 131.

In one embodiment, the intermediate substrate 120 may be formed by cutting a silicon wafer, and conductive traces are provided on two opposite surfaces of the silicon wafer to form the conductive traces 123 and 124 on the first surface 121 and the second surface 122 of the intermediate substrate 120, respectively.

In another embodiment, the first conductive bumps 131 are metal bumps formed on the second surface 122 of the intermediate substrate 120 using a bumping process. The first conductive bumps 131 may be composed of eutectic, lead free, high lead materials, or copper pillars. The intermediate substrate 120 is attached to the first surface 111 of the base substrate 110 using flip chip technology.

A die 150 is disposed on the first surface 121 of the intermediate substrate 120. The die 150 has an active surface and a back surface opposite to the active surface. A plurality of second conductive bumps 132 is disposed on the active surface of the die 150. The second conductive bumps 132 are electrically connected to the die 150. The second conductive bumps 132 are sandwiched between the die 150 and the intermediate substrate 120. The second conductive bumps 132 are electrically connected to the first conductive bumps 131 through the conductive traces 123, 124 on the first surface 121 and the second surface 122 of the intermediate substrate 120, so that the die 150 may be electrically connected to the base substrate 110. A gap between the die 150 and the intermediate substrate 120 is infiltrated with underfill to cover the second conductive bumps 132.

In the present disclosure, the die 150 may be a graphics processing unit (GPU).

In one embodiment, the second conductive bumps 132 are metal bumps formed on the active surface of the die 150 using a bumping process. The second conductive bumps 132 may be composed of eutectic, lead free, high lead materials, or copper pillars. The die 150 is attached to the first surface 121 of the intermediate substrate 120 using flip chip technology.

A semiconductor memory stack 160 is disposed on the first surface 121 of the intermediate substrate 120. The semiconductor memory stack 160 is formed by stacking at least a plurality of memory dies. The semiconductor memory stack 160 is disposed side by side with the die 150.

In one embodiment, the semiconductor memory stack 160 is a high bandwidth memory (HBM) stack.

A plurality of third conductive bumps 133 is disposed on the bottom of the semiconductor memory stack 160. The third conductive bumps 133 are electrically connected to the semiconductor memory stack 160. The third conductive bumps 133 are sandwiched between the semiconductor memory stack 160 and the intermediate substrate 120. The third conductive bumps 133 are electrically connected to the first conductive bumps 131 through the conductive traces 123, 124 on the first surface 121 and the second surface 122 of the intermediate substrate 120, so that the semiconductor memory stack 160 may be electrically connected to the base substrate 110. A gap between the semiconductor memory stack 160 and the intermediate substrate 120 is infiltrated with underfill to cover the third conductive bumps 133.

A plurality of solder balls 190 is disposed on the second surface 112 of the base substrate 110 and electrically connected to the base substrate 110. The solder balls 190 are electrically connected to the first conductive bumps 131 through the conductive traces 113, 114, and the conductive vias 115 in the base substrate 110, so that the die 150 and the semiconductor memory stack 160 may be electrically connected to an external circuit through the intermediate substrate 120 and the base substrate 110 using the solder balls 190.

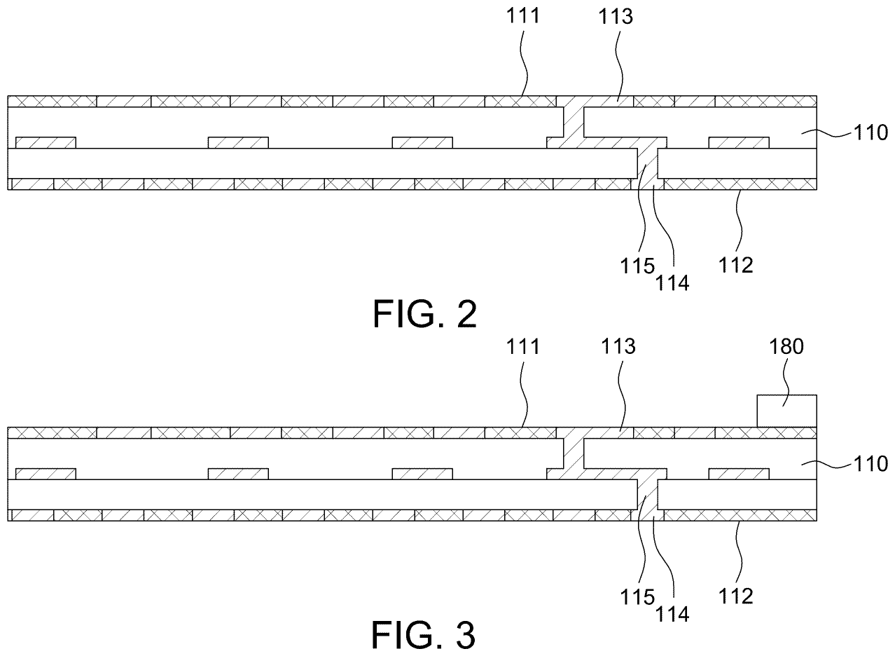

Referring to FIGS. 2 to 9, which illustrate a method of manufacturing the semiconductor package of FIG. 1. As shown in FIG. 2, a base substrate 110 is provided. The base substrate 110 has opposing first surface 111 and second surface 112, and the first surface 111 and the second surface 112 are located on different planes. For example, the first surface 111 is a top surface and the second surface 112 is a bottom surface, but is not limited thereto. The first surface 111 and the second surface 112 of the base substrate 110 are formed with a conductive trace 113 and a conductive trace 114 thereon, respectively. The conductive traces 113 and 114 are electrically connected to each other by a plurality of conductive vias 115 penetrating the base substrate 110 from the first surface 111 to the second surface 112.

In one embodiment, the base substrate 110 may be a single-layer or multi-layer circuit board, a redistribution layer substrate or a glass substrate.

As shown in FIG. 3, a plurality of passive components 180 may be then mounted on the first surface 111 of the base substrate 110 as desired.

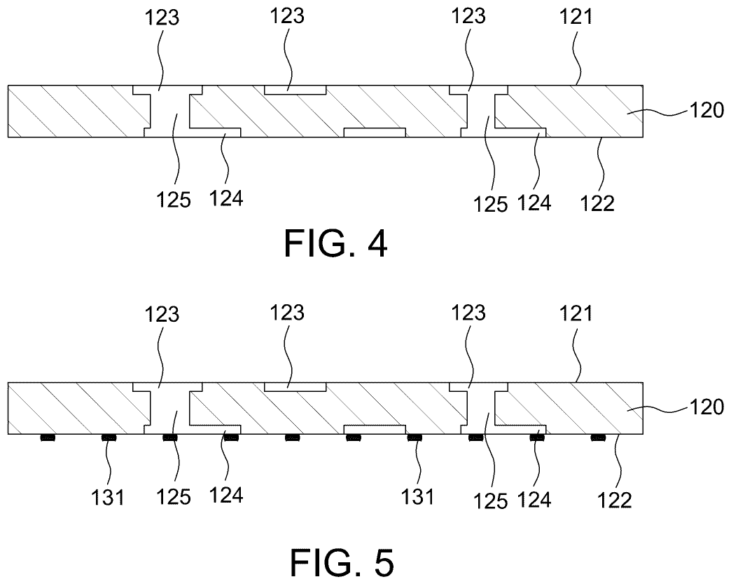

As shown in FIG. 4, an intermediate substrate 120 is provided. The intermediate substrate 120 may be a silicon substrate and be constructed of silicon. The intermediate substrate 120 has opposing first surface 121 and second surface 122, and the first surface 121 and the second surface 122 are located on different planes. For example, the first surface 121 is a top surface and the second surface 122 is a bottom surface, but is not limited thereto. The first surface 121 and the second surface 122 of the intermediate substrate 120 are formed with a conductive trace 123 and a conductive trace 124 thereon, respectively. The conductive traces 123 and 124 are electrically connected to each other by a plurality of conductive vias 125 penetrating the intermediate substrate 120 from the first surface 121 to the second surface 122.

As shown in FIG. 5, a plurality of first conductive bumps 131 is then formed on the second surface 122 of the intermediate substrate 120 and electrically connected to the intermediate substrate 120.

In one embodiment, the intermediate substrate 120 may be formed by cutting a silicon wafer, and conductive traces are provided on two opposite surfaces of the silicon wafer to form the conductive traces 123 and 124 on the first surface 121 and the second surface 122 of the intermediate substrate 120, respectively. In the present disclosure, the conductive trace 123 includes circuits for connecting a computing processor with a memory, and logic circuits for a high-computing memory.

In another embodiment, the first conductive bumps 131 are metal bumps formed on the second surface 122 of the intermediate substrate 120 using a bumping process. The first conductive bumps 131 may be composed of eutectic, lead free, high lead materials, or copper pillars.

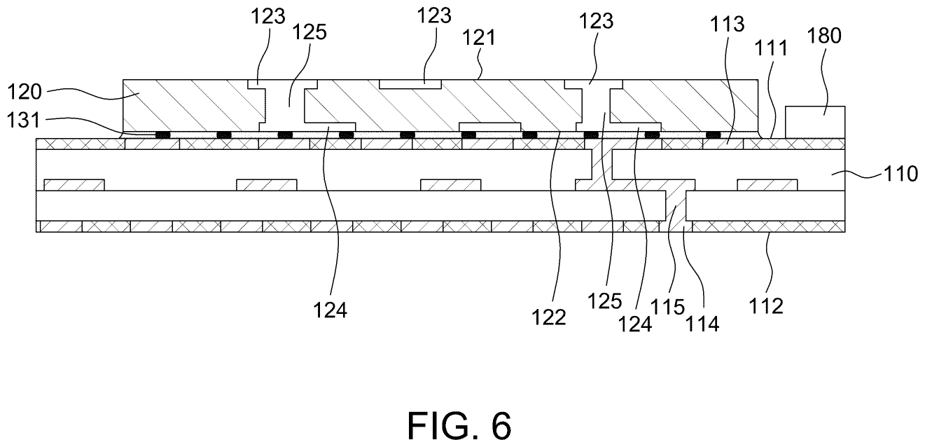

As shown in FIG. 6, the intermediate substrate 120 is then attached to the first surface 111 of the base substrate 110 using flip chip technology such that the first conductive bumps 131 are sandwiched between the intermediate substrate 120 and the base substrate 110. The intermediate substrate 120 is electrically connected to the base substrate 110 through the first conductive bumps 131. A gap between the intermediate substrate 120 and the base substrate 110 may be infiltrated with underfill to cover the first conductive bumps 131.

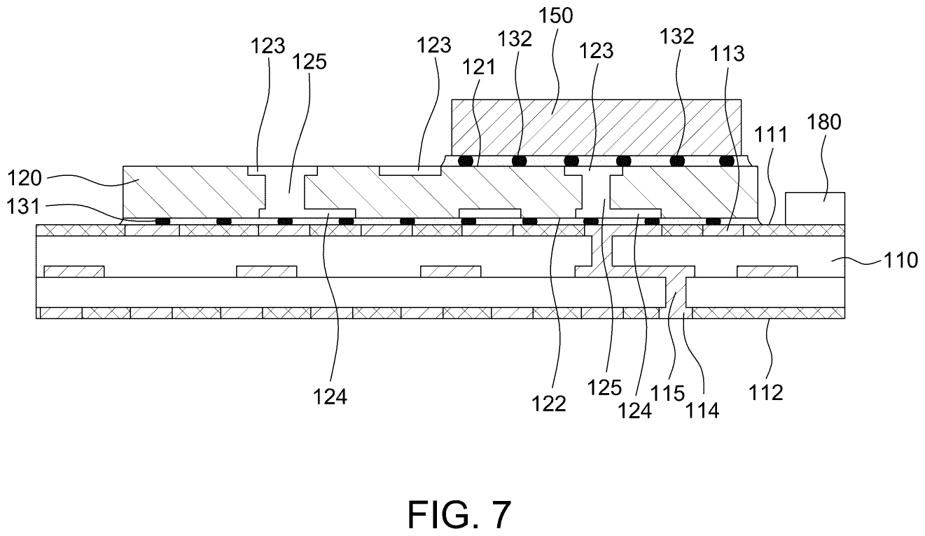

As shown in FIG. 7, a die 150 is provided. The die 150 has an active surface and a back surface opposite to the active surface. A plurality of second conductive bumps 132 is disposed on the active surface of the die 150. The second conductive bumps 132 are electrically connected to the die 150. The die 150 is then attached to the first surface 121 of the intermediate substrate 120 using flip chip technology such that the second conductive bumps 132 are sandwiched between the die 150 and the intermediate substrate 120. The second conductive bumps 132 are electrically connected to the first conductive bumps 131 through the conductive traces 123, 124 on the first surface 121 and the second surface 122 of the intermediate substrate 120, so that the die 150 may be electrically connected to the base substrate 110. A gap between the die 150 and the intermediate substrate 120 may be infiltrated with underfill to cover the second conductive bumps 132.

In the present disclosure, the die 150 may be a graphics processing unit (GPU).

In one embodiment, the second conductive bumps 132 are metal bumps formed on the active surface of the die 150 using a bumping process. The second conductive bumps 132 may be composed of eutectic, lead free, high lead materials, or copper pillars.

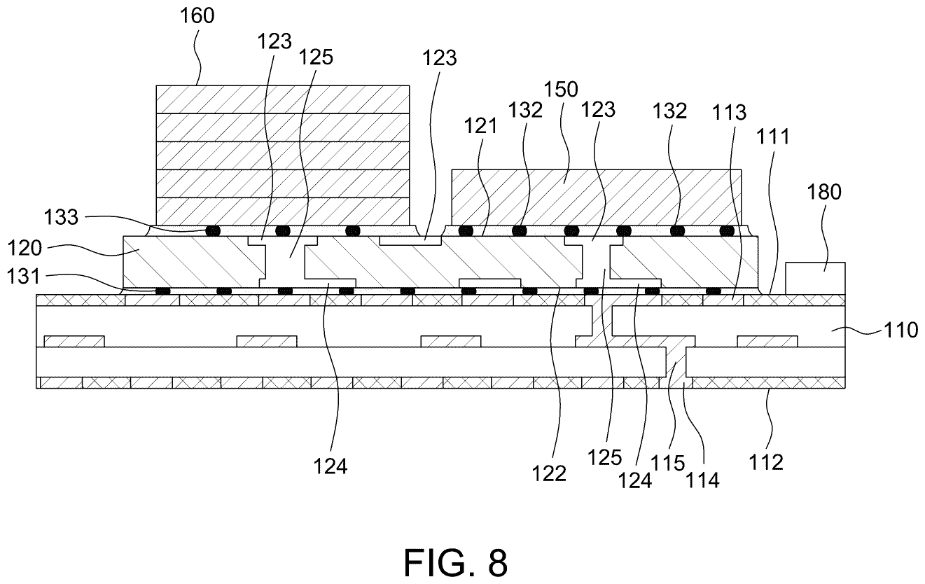

As shown in FIG. 8, a semiconductor memory stack 160 is provided. The semiconductor memory stack 160 is formed by stacking at least a plurality of memory dies. A plurality of third conductive bumps 133 is disposed on the bottom of the semiconductor memory stack 160. The third conductive bumps 133 are electrically connected to the semiconductor memory stack 160.

In one embodiment, the semiconductor memory stack 160 is a high bandwidth memory (HBM) stack.

The semiconductor memory stack 160 is then attached to the first surface 121 of the intermediate substrate 120 using flip chip technology such that the third conductive bumps 133 are sandwiched between the semiconductor memory stack 160 and the intermediate substrate 120. The semiconductor memory stack 160 is disposed side by side with the die 150.

The third conductive bumps 133 are electrically connected to the first conductive bumps 131 through the conductive traces 123, 124 on the first surface 121 and the second surface 122 of the intermediate substrate 120, so that the semiconductor memory stack 160 may be electrically connected to the base substrate 110. A gap between the semiconductor memory stack 160 and the intermediate substrate 120 may be infiltrated with underfill to cover the third conductive bumps 133.

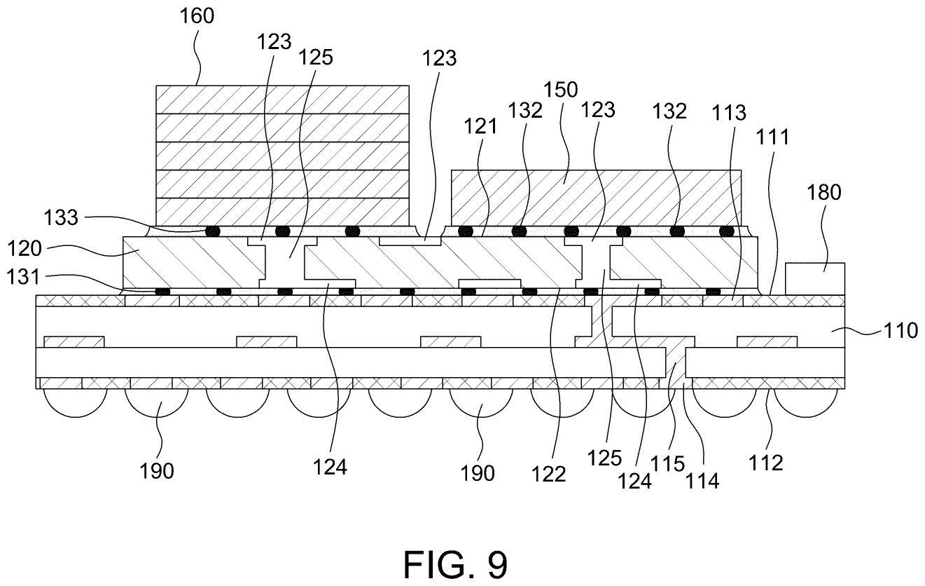

As shown in FIG. 9, a plurality of solder balls 190 is then disposed on the second surface 112 of the base substrate 110 and electrically connected to the base substrate 110 so as to form the semiconductor package of FIG. 1.

The solder balls 190 are electrically connected to the first conductive bumps 131 through the conductive traces 113, 114, and the conductive vias 115 in the base substrate 110, so that the die 150 and the semiconductor memory stack 160 may be electrically connected to an external circuit through the intermediate substrate 120 and the base substrate 110 using the solder balls 190.

The semiconductor packages of the present disclosure have lower manufacturing costs and higher production yields.

Although the preferred embodiments of the disclosure have been disclosed for illustrative purposes, those skilled in the art will appreciate that various modifications, additions and substitutions are possible, without departing from the scope and spirit of the disclosure as disclosed in the accompanying claims.

1. A semiconductor package, comprising:
a base substrate;
an intermediate substrate disposed on the base substrate;
a plurality of first conductive bumps disposed between the base substrate and the intermediate substrate, the first conductive bumps being electrically connected to the base substrate and the intermediate substrate;
a graphics processing unit disposed on the intermediate substrate; and
a plurality of second conductive bumps disposed between the intermediate substrate and the graphics processing unit, the second conductive bumps being electrically connected to the intermediate substrate and the graphics processing unit,
wherein the second conductive bumps are electrically connected to the first conductive bumps through the intermediate substrate.

2. The semiconductor package as claimed in claim 1, further comprising:
a semiconductor memory stack attached to the intermediate substrate; and
a plurality of third conductive bumps disposed between the intermediate substrate and the semiconductor memory stack, the third conductive bumps being electrically connected to the intermediate substrate and the semiconductor memory stack,
wherein the third conductive bumps are electrically connected to the first conductive bumps through the intermediate substrate.

3. The semiconductor package as claimed in claim 1, wherein the intermediate substrate is constructed of silicon.

4. The semiconductor package as claimed in claim 1, wherein the semiconductor memory stack is a high bandwidth memory stack.

5. The semiconductor package as claimed in claim 1, wherein the intermediate substrate has opposing first surface and second surface, the semiconductor package further comprising:
a first conductive trace formed on the first surface, the first conductive trace being electrically connected to the second conductive bumps;
a second conductive trace formed on the second surface, the second conductive trace being electrically connected to the first conductive bumps; and
a plurality of conductive vias formed in the intermediate substrate, the conductive vias being electrically connected to the first conductive trace and the second conductive trace.

6. A method of manufacturing a semiconductor package, comprising:
forming a plurality of first conductive bumps on an intermediate substrate;
disposing the intermediate substrate on a base substrate such that the first conductive bumps are disposed between the base substrate and the intermediate substrate and the first conductive bumps are electrically connected to the base substrate and the intermediate substrate;
forming a plurality of second conductive bumps on a graphics processing unit; and
disposing the graphics processing unit on the intermediate substrate such that the second conductive bumps are disposed between the intermediate substrate and the graphics processing unit and the second conductive bumps are electrically connected to the intermediate substrate and the graphics processing unit,
wherein the second conductive bumps are electrically connected to the first conductive bumps through the intermediate substrate.

7. The method as claimed in claim 6, further comprising:
forming a plurality of third conductive bumps on a semiconductor memory stack; and
disposing the semiconductor memory stack on the intermediate substrate such that the third conductive bumps are disposed between the intermediate substrate and the semiconductor memory stack and the third conductive bumps are electrically connected to the intermediate substrate and the semiconductor memory stack,
wherein the third conductive bumps are electrically connected to the first conductive bumps through the intermediate substrate.

8. The method as claimed in claim 6, wherein the intermediate substrate is constructed of silicon.

9. The method as claimed in claim 6, wherein the semiconductor memory stack is a high bandwidth memory stack.

10. The method as claimed in claim 6, wherein the intermediate substrate has opposing first surface and second surface, the method further comprising:
forming a first conductive trace on the first surface, the first conductive trace being electrically connected to the second conductive bumps;
forming a second conductive trace on the second surface, the second conductive trace being electrically connected to the first conductive bumps; and
forming a plurality of conductive vias in the intermediate substrate, the conductive vias being electrically connected to the first conductive trace and the second conductive trace.
